(19) United States
(12) Patent Application Publication
(10) Pub. No.: US 2018/0287572 A1
(43) Pub. Date: Oct. 4, 2018

(54) POWER SOURCE CIRCUIT

(71) Applicant: FUJITSU LIMITED, Kawasaki-shi (JP)

(72) Inventor: Kazuaki Oishi, Yokohama (JP)

(73) Assignee: FUJITSU LIMITED, Kawasaki-shi (JP)

(21) Appl. No.: 15/925,367

(22) Filed: Mar. 19, 2018

(30) Foreign Application Priority Data
Mar. 29, 2017 (JP) 2017-065426

(51) Int. Cl. H03F 3/193; H03F 3/21; H03F 1/02

(52) U.S. Cl. CPC H03F 3/193; H03F 3/21; H03F 2200/451; H03F 2200/102; H03F 1/0211

(57) ABSTRACT

A power source circuit includes a linear regulator including: an amplifier configured to amplify an envelope signal for representing an envelope of an input signal input into a power amplifier, and an output stage including transistors, configured to output power output to be supplied to the power amplifier in accordance with amplified output of the amplifier; a monitor circuit configured to monitor the envelope signal; and a switched-capacitor circuit configured to generate a power source voltage higher than a voltage of the power output based on a monitoring result of the monitor circuit, wherein the switched-capacitor circuit does not supply the power source voltage to the amplifier, but supplies the power source voltage to the output stage.

### CROSS-REFERENCE TO RELATED APPLICATION

This application is based upon and claims the benefit of priority of the prior Japanese Patent Application No. 2017-65426, filed on Mar. 29, 2017, the entire contents of which are incorporated herein by reference.

### FIELD

The embodiments discussed herein are related to a power source circuit.

### BACKGROUND

To date, as a power source control technique for a power amplifier, envelope tracking has been known that realizes an increase in the efficiency of the power amplifier (for example, refer to Japanese Laid-open Patent Publication No. 2014-45335 and Japanese National Publication of International Patent Application Nos. 2016-506231 and 2015-526059). A power source circuit used for envelope tracking raises or lowers the voltage of the power output to be supplied to a power amplifier in accordance with the envelope of a signal input to the power amplifier. Thereby, the efficiency of the power amplifier is improved.

A power source circuit used for envelope tracking controls the power output voltage (the power source voltage to a power amplifier) supplied to a power amplifier such that the power output voltage becomes equal to or higher than the voltage of the output signal of the power amplifier in order to keep the output signal of the power amplifier undistorted. However, the maximum voltage of the power output supplied from the power source circuit to the power amplifier is limited to the power source voltage (the power source voltage of the power source circuit) that is supplied to the power source circuit. When the maximum voltage of the power output supplied from the power source circuit to the power amplifier is limited to the power source voltage of the power source circuit, there is a risk of distorting the output signal of the power amplifier depending the magnitude of the output signal voltage of the power amplifier.

Thus, according to the present disclosure, it is desirable to provide a power source circuit capable of avoiding distortion of the output signal of a power amplifier.

### SUMMARY

According to an aspect of the embodiments, a power source circuit includes a linear regulator including: an amplifier configured to amplify an envelope signal for representing an envelope of an input signal input into a power amplifier, and an output stage including transistors, configured to output power output to be supplied to the power amplifier in accordance with amplified output of the amplifier; a monitor circuit configured to monitor the envelope signal; and a switched-capacitor circuit configured to generate a power source voltage higher than a voltage of the power output based on a monitoring result of the monitor circuit, wherein the switched-capacitor circuit does not supply the power source voltage to the amplifier, but supplies the power source voltage to the output stage.

The object and advantages of the invention will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating an example of the configuration of a communication device;

FIG. 2 is a diagram illustrating an example of the configuration of a power source circuit;

FIGS. 3A and 3B are diagrams illustrating examples of output of a power amplifier at normal time and at deterioration time respectively;

FIGS. 4A and 4B are diagrams illustrating examples of output of a power amplifier in the case where the power source voltage supplied to an output stage is fixed and in the case where the power source voltage supplied to an output stage is variable respectively;

FIG. 5A is a diagram illustrating a specific example of the configuration of the power source circuit;

FIG. 5B is a diagram illustrating an example of the configuration of a linear regulator;

FIG. 5C is a diagram illustrating an example of the configuration of a linear regulator;

FIG. 6 is a diagram illustrating an example of the configuration of a non-overlap circuit;

FIG. 7 is a diagram illustrating an example of the configuration of a switching regulator;

FIG. 8 is a timing chart illustrating an example when a switched-capacitor circuit has a step-up configuration;

FIG. 9 is a diagram illustrating an example when a switched-capacitor circuit has a step-down configuration;

FIG. 10 is a timing chart illustrating an example when a switched-capacitor circuit has a step-down configuration;

FIG. 11 is a diagram illustrating an example when the switched-capacitor circuit has another step-up configuration;

FIG. 12 is a diagram illustrating an example when the switched-capacitor circuit has another step-down configuration;

FIG. 13 is a diagram illustrating another example of the configuration of an output stage;

FIGS. 14A, 14B, and 14C are diagrams illustrating a plurality of respective examples of the configuration of a bias voltage generator;

FIG. 15 is a diagram illustrating another example of the configuration of an output stage; and

FIG. 16 is a diagram illustrating another example of the configuration of a monitor circuit.

### DESCRIPTION OF EMBODIMENTS

In the following, a description will be given of the present embodiment with reference to the drawings.

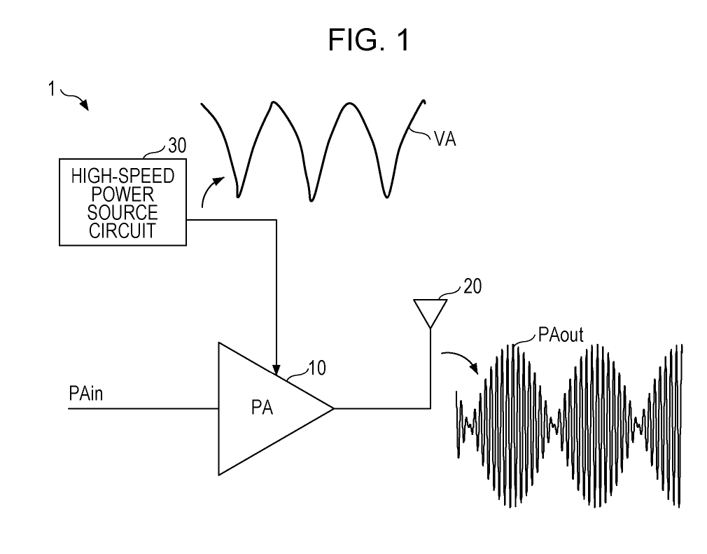

FIG. 1 is a diagram illustrating an example of the configuration of a communication device for which a power source circuit according to the present embodiment is used. A communication device 1 illustrated in FIG. 1 is an example of a communication device including an antenna to which power is supplied by a power amplifier. As a specific example of the communication device 1, a wireless terminal device (mobile phone, smartphone, Internet of Things (IoT) device, or the like), a wireless base station, or the like is given. The communication device 1 includes a power amplifier (PA) 10, an antenna 20, a high-speed power source circuit 30 (hereinafter referred to as a “power source circuit 30”).

The power amplifier 10 amplifies a high frequency signal PAin. The power amplifier 10 supplies an output signal PAout produced by amplifying the high frequency signal PAin to the antenna 20. The output signal PAout of the power amplifier 10 is supplied to the antenna 20, and thus the antenna 20 transmits a radio wave so as to make it possible to perform wireless communication. The high frequency signal PAin is an example of an input signal and is a signal input into the power amplifier 10 to be amplified. The high frequency signal PAin is, for example, a modulated signal the amplitude of which varies.

The power source circuit 30 is an example of the power source circuit that generates a power source voltage VA (power source voltage VA of the power amplifier 10) supplied to the power amplifier 10. The power source circuit 30 controls the power source voltage VA to be supplied to the power amplifier 10 upward and downward in accordance with the voltage of an envelope signal indicating the envelope of the high frequency signal PAin so as to realize high efficiency and low power consumption of the power amplifier 10. The power source circuit 30 controls the power source voltage VA supplied to the power amplifier 10 so that the power source voltage VA becomes equal to or higher than the output signal PAout of the power amplifier in order to keep the output signal PAout of the power amplifier 10 undistorted.

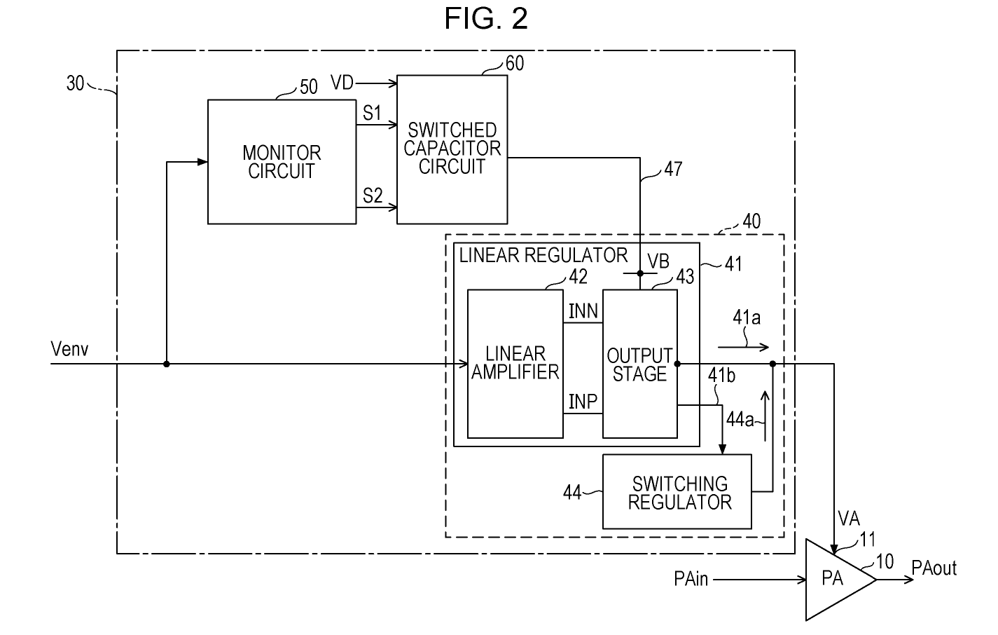

FIG. 2 is a diagram illustrating an example of the configuration of a power source circuit. The power source circuit 30 illustrated in FIG. 2 includes a regulator 40, a monitor circuit 50, and a switched-capacitor circuit 60.

The regulator 40 controls the power source voltage VA supplied to the power terminal 11 of the power amplifier 10 in accordance with the voltage of an envelope signal (hereinafter referred to as an “envelope voltage Venv”) indicating the envelope of the high frequency signal PAin so that the power source voltage VA becomes equal to or higher than the output signal PAout of the power amplifier. The regulator 40 includes a linear regulator 41 and a switching regulator 44.

The linear regulator 41 linearly amplifies the envelope voltage Venv. The linear regulator 41 supplies a power output 41a, which is an output produced by linearly amplifying the envelope voltage Venv, to the power terminal 11 of the power amplifier 10. The linear regulator 41 includes a linear amplifier 42 and an output stage 43.

The linear amplifier 42 is an example of the amplifier that amplifies the envelope signal. The linear amplifier 42 operates in accordance with the envelope voltage Venv. The linear amplifier 42 outputs differential amplified outputs INN and INP to the output stage 43. The linear amplifier 42 may be a circuit that outputs a single ended signal in accordance with the envelope voltage Venv depending on the configuration of the output stage 43. Also, the linear amplifier 42 may have the configuration of an inverting amplifier or a non-inverting amplifier, in which the output of the output stage 43 is fed back to the input of the linear amplifier 42 via a resistor.

The output stage 43 outputs the power output 41a supplied to the power terminal 11 of the power amplifier 10 in accordance with the outputs INN and INP that are output from the linear amplifier 42.

The monitor circuit 50 is an example of the monitor circuit that monitors the envelope signal. The monitor circuit 50 monitors the envelope voltage Venv and outputs a pair of switch signals S1 and S2, which is an example of a monitoring result, to the switched-capacitor circuit 60.

Based on the monitoring result of the monitor circuit 50, the switched-capacitor circuit 60 generates a power source voltage VB which is higher than the voltage (power source voltage VA) of the power output 41a based on the direct current voltage VD. The switched-capacitor circuit 60 does not supply the power source voltage VB to the linear amplifier 42, but supplies the power source voltage VB to the output stage 43 via a supply line 47. The supply line 47 denotes a power line that connects the switched-capacitor circuit 60 and the output stage 43.

The direct current voltage VD denotes a direct-current power source voltage supplied from a direct current power source, for example, a lithium-ion secondary battery, or the like. The direct current voltage VD may be used as the power source voltage of, for example, the monitor circuit 50, the linear amplifier 42, and the switching regulator 44.

The switching regulator 44 is an example of a switching amplifier and generates a power output 44a supplied to the power terminal 11 of the power amplifier 10. The switching regulator 44 generates the power output 44a based on, for example, an output signal 41b output from the output stage 43. The switching regulator 44 may generate the power output 44a based on a signal different from the output signal 41b.

The switching regulator 44 has higher efficiency but a slower response speed compared with the linear regulator 41. The regulator 40 controls the power source voltage VA with high efficiency and with high precision using the combination of the power output 41a and the power output 44a by the collaboration of the linear regulator 41 having low efficiency and a high speed with the switching regulator 44 having high efficiency and a low speed. In this regard, if sufficient efficiency is obtained without using the switching regulator 44, the switching regulator 44 may not be provided.

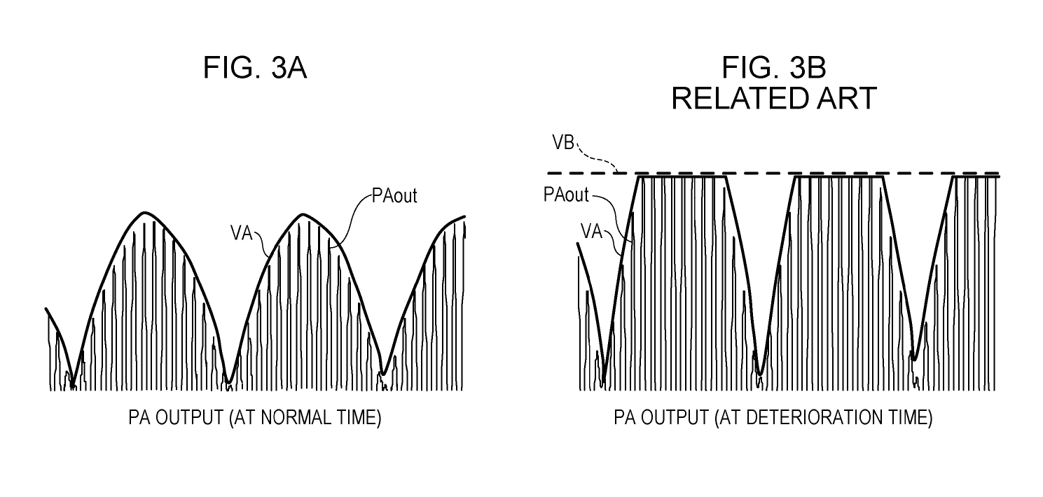

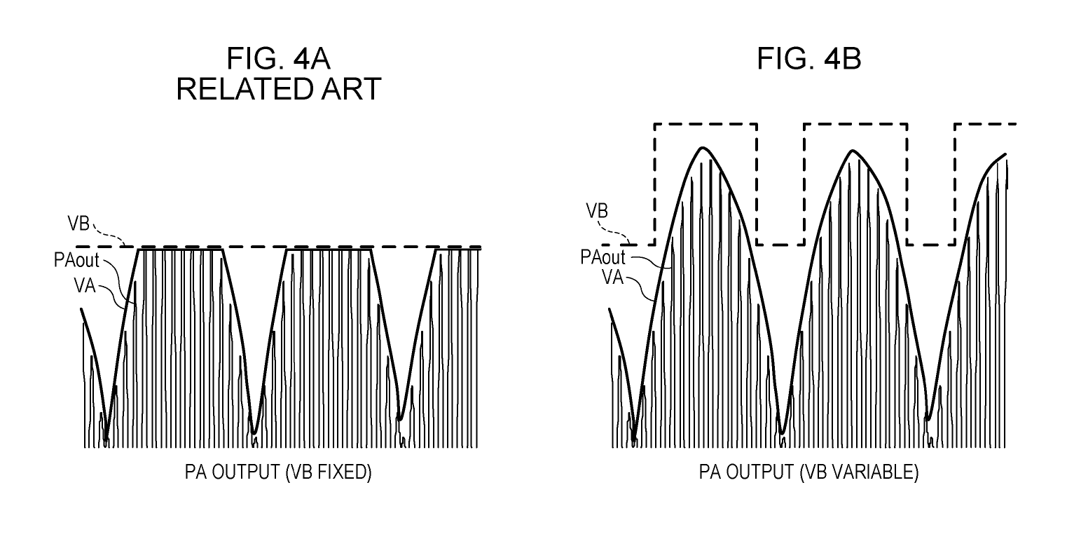

FIGS. 3A and 3B are diagrams illustrating examples of output of a power amplifier at normal time and at deterioration time respectively. FIGS. 4A and 4B are diagrams illustrating examples of output of a power amplifier in the case where the power source voltage supplied to the output stage is fixed and in the case where the power source voltage supplied to the output stage is variable respectively. In this regard, in FIGS. 3A, 3B, 4A, and 4B, a lower half of the output signal PAout is omitted.

In order to avoid distortion of the output signal PAout of the power amplifier 10, the power source circuit 30 changes the power source voltage VA in accordance with the envelope voltage Venv so that the power source voltage VA varies along the envelope of the output signal PAout (refer to FIG. 3A). However, in the related-art, if the output of the power amplifier is attempted to be raised, the upper limit of the power source voltage VA of the power amplifier is limited to a fixed power source voltage VB of the power source circuit that supplies the power source voltage VA. As a result, as illustrated in FIG. 3B and FIG. 4A, peaks of the output signal PAout are cut in the power source voltage VB, and thus distortion (deterioration) occurs in the output signal PAout.

In contrast, the power source circuit 30 according to the present embodiment includes a switched-capacitor circuit 60 capable of generating a power source voltage VB higher than the power source voltage VA of the power amplifier 10. As illustrated in FIG. 4B, by generating the power source voltage VB higher than the power source voltage VA, the upper limit of the power source voltage VA is not limited by the power source voltage VB. As a result, when the output of the power amplifier 10 is raised, it is possible to avoid distortion of the output signal PAout.

Accordingly, with the power source circuit 30 illustrated in FIG. 2, the power source voltage VB, which is higher than the power source voltage VA, is supplied to the output stage 43 of the linear regulator 41, and thus it is possible to avoid distortion of the output signal PAout.

Also, the switched-capacitor circuit 60 of the power source circuit 30 does not supply the power source voltage VB, which is higher than the power source voltage VA, to the linear amplifier 42, but supplies the power source voltage VB to the output stage 43. Thereby, it is possible to set the withstand voltage of the linear amplifier 42 lower compared with the withstand voltage of the output stage 43 against the power source voltage VB. Accordingly, it becomes easy to secure the withstand voltage of the linear amplifier 42. Also, since it is possible to lower the power source voltage supplied to the linear amplifier 42 than the power source voltage VB supplied to the output stage 43, it is possible to reduce the power consumption of the power source circuit 30. Further, it becomes possible not to change the power source voltage to the linear amplifier 42 without changing both of the power source voltages to the linear amplifier 42 and to the output stage 43. For example, the power source voltage to the linear amplifier 42 may be the fixed direct current voltage VD. Accordingly, as the number of places to which the power source voltage is changed is reduced, it is possible to reduce the occurrence of noise caused by the variations of the power source voltage.

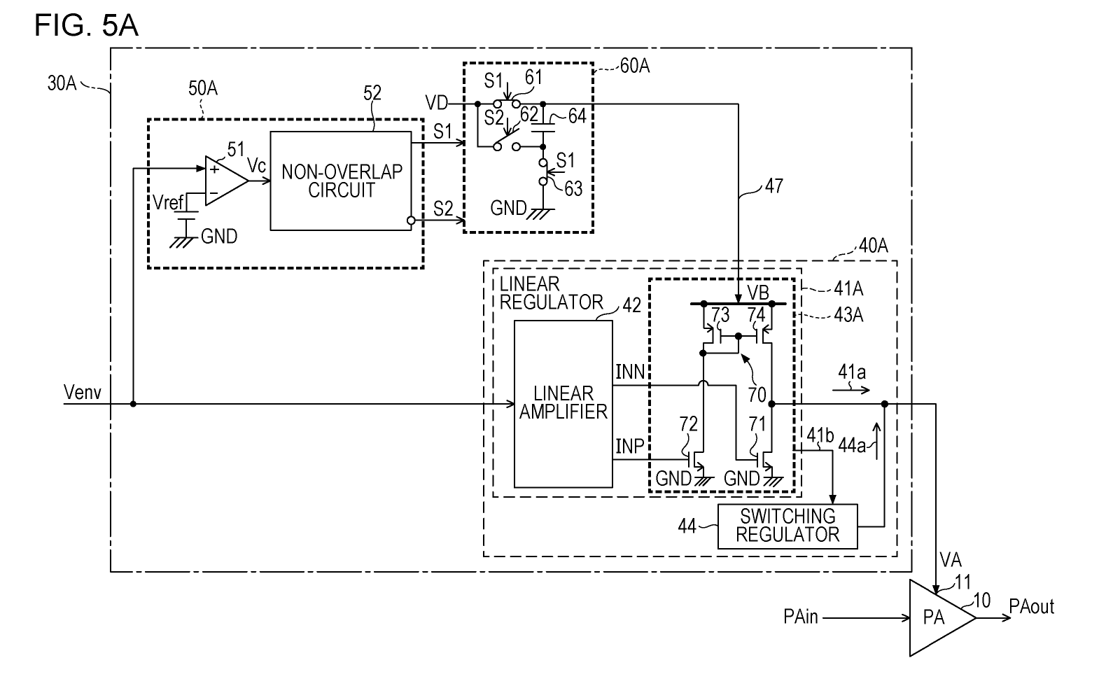

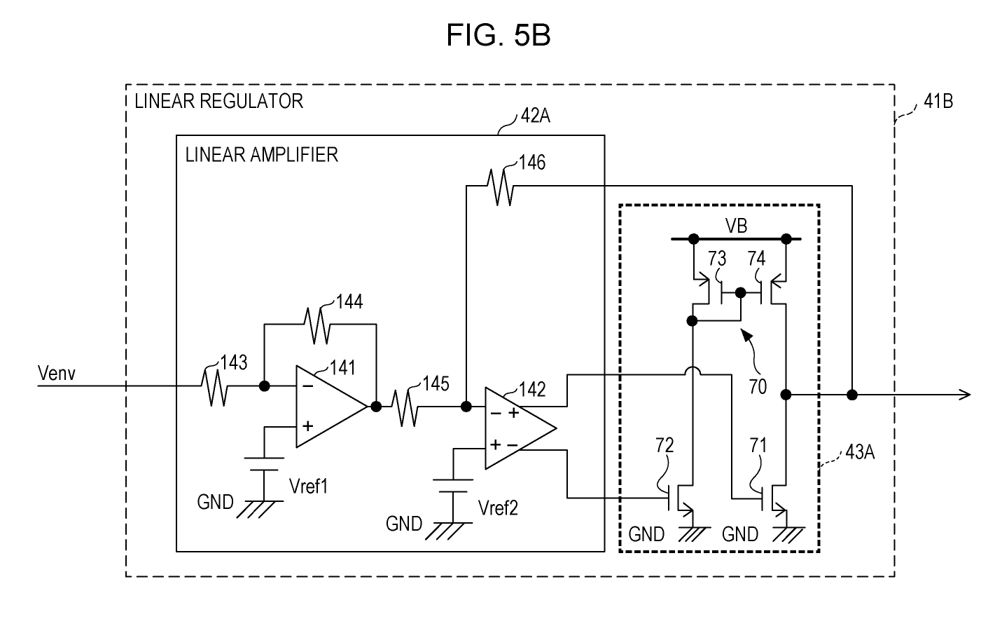

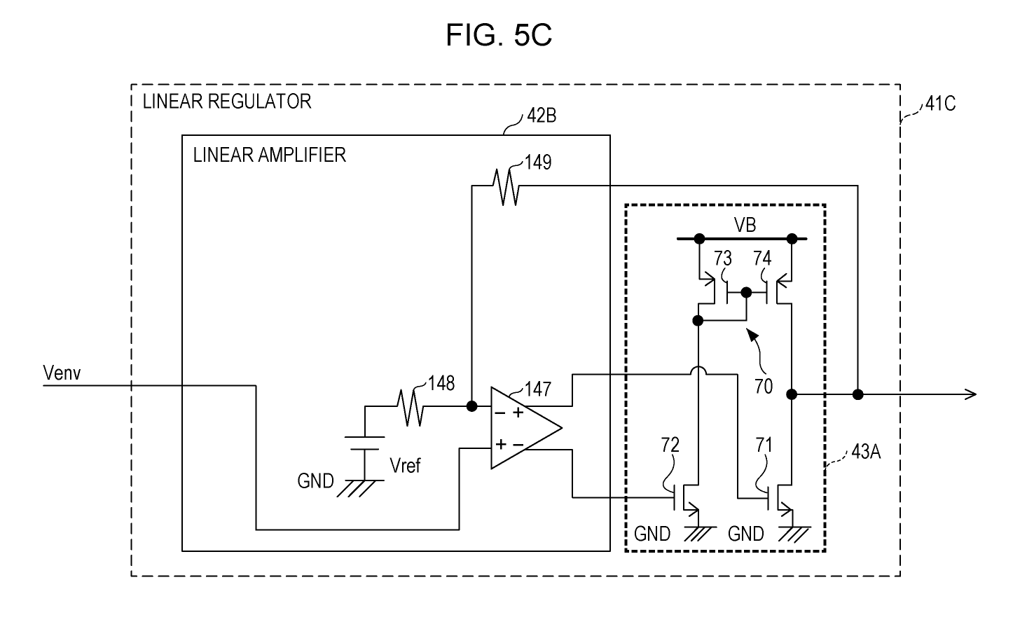

FIG. 5A is a diagram illustrating a specific example of the configuration of the power source circuit. A power source circuit 30A illustrated in FIG. 5A is an example of the power source circuit 30 illustrated in FIG. 2. The power source circuit 30A includes a regulator 40A, a monitor circuit 50A, and a switched-capacitor circuit 60A. The regulator 40A, the monitor circuit 50A, and the switched-capacitor circuit 60A are respective examples of the regulator 40, the monitor circuit 50, and the switched-capacitor circuit 60 illustrated in FIG. 2. The regulator 40A includes a linear regulator 41A and a switching regulator 44. The linear regulator 41A includes a linear amplifier 42 and an output stage 43A. The linear regulator 41A and the output stage 43A are respective examples of the linear regulator 41 and the output stage 43 illustrated in FIG. 2.

FIG. 5B is a diagram illustrating an example of the configuration of the linear regulator. The linear regulator 41B illustrated in FIG. 5B includes a linear amplifier 42A and the output stage 43A. The linear regulator 41B, the linear amplifier 42A, and the output stage 43A are respective examples of the linear regulator 41, the linear amplifier 42, and the output stage 43 that are illustrated in FIG. 2. The linear amplifier 42A has the configuration of an inverting amplifier in which the output of the output stage 43A is fed back to the linear amplifier 42A via a resistor 146.

Specifically, the linear amplifier 42A includes amplifiers 141 and 142, and resistors 143 to 146. One end of the resistor 143 is connected to the potential of the envelope voltage Venv. The amplifier 141 includes a non-inverted input terminal to which a reference voltage Vref1 is input, and an inverted input terminal to which the other end of the resistor 143 and one end of the resistor 144 are connected. The output terminal of the amplifier 141 is connected to the other end of the resistor 144 and one end of the resistor 145. The amplifier 142 includes a non-inverted input terminal to which a reference voltage Vref2 is input, and an inverted input terminal to which the other end of the resistor 145 and one end of the resistor 146 are connected. The other end of the resistor 146 is connected to an output node to which the drain of an output transistor 74 and the drain of a transistor 71 are connected.

FIG. 5C is a diagram illustrating an example of the configuration of a linear regulator. The linear regulator 41C illustrated in FIG. 5C includes a linear amplifier 42B and the output stage 43A. The linear regulator 41C, the linear amplifier 42B, and the output stage 43A are respective examples of the linear regulator 41, the linear amplifier 42, and the output stage 43 that are illustrated in FIG. 2. The linear amplifier 42B has the configuration of a non-inverting amplifier in which the output of the output stage 43A is fed back to the linear amplifier 42B via a resistor 149.

Specifically, the linear amplifier 42B includes an amplifier 147, and resistors 148 and 149. One end of the resistor 148 is connected to the potential of a reference voltage Vref. The amplifier 147 has a non-inverted input terminal to which the envelope voltage Venv is input, and an inverted input terminal to which the other end of the resistor 148 and one end of the resistor 149 are connected. The other end of the resistor 149 is connected to an output node to which the drain of the output transistor 74 and the drain of the transistor 71 are connected.

In FIG. 5A, the monitor circuit 50A includes a comparator 51 and a non-overlap circuit 52. The comparator 51 is an example of a voltage detection circuit that detects the envelope voltage Venv. The comparator 51 compares the envelope voltage Venv with a predetermined reference voltage Vref and outputs a determination signal Vc indicating a comparison result of the magnitude relationship. For example, if the envelope voltage Venv is lower than the reference voltage Vref, the comparator 51 outputs the determination signal Vc the logical level of which is inactive (for example, a low level). On the other hand, if the envelope voltage Venv is equal to or higher than the reference voltage Vref, the comparator 51 outputs the determination signal Vc the logical level of which is active (for example, a high level).

The non-overlap circuit 52 is an example of a drive circuit that drives the switched-capacitor circuit 60 such that the power source voltage VB higher than the power source voltage VA is generated based on the determination signal Vc indicating the comparison result of the comparator 51. The non-overlap circuit 52 outputs two switch signals 51 and S2 in accordance with the determination signal Vc. Neither of the two switch signals 51 and S2 becomes active (for example, a high level) in a period having the same logical level.

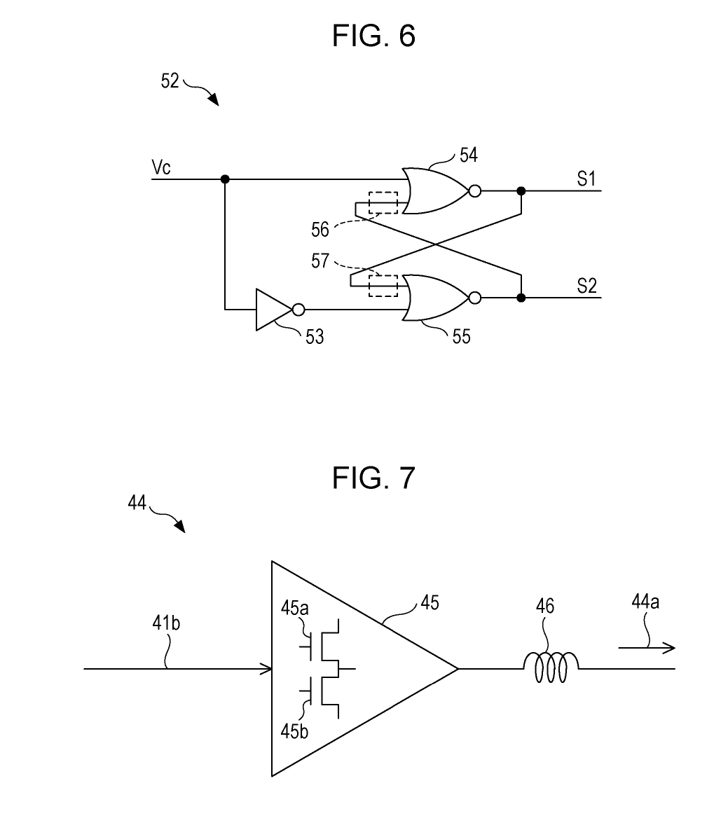

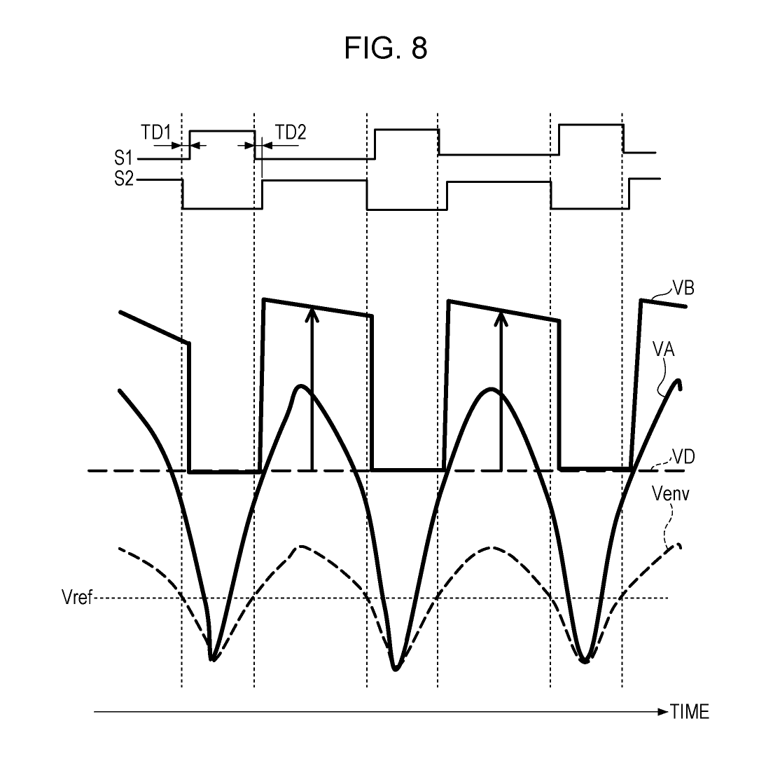

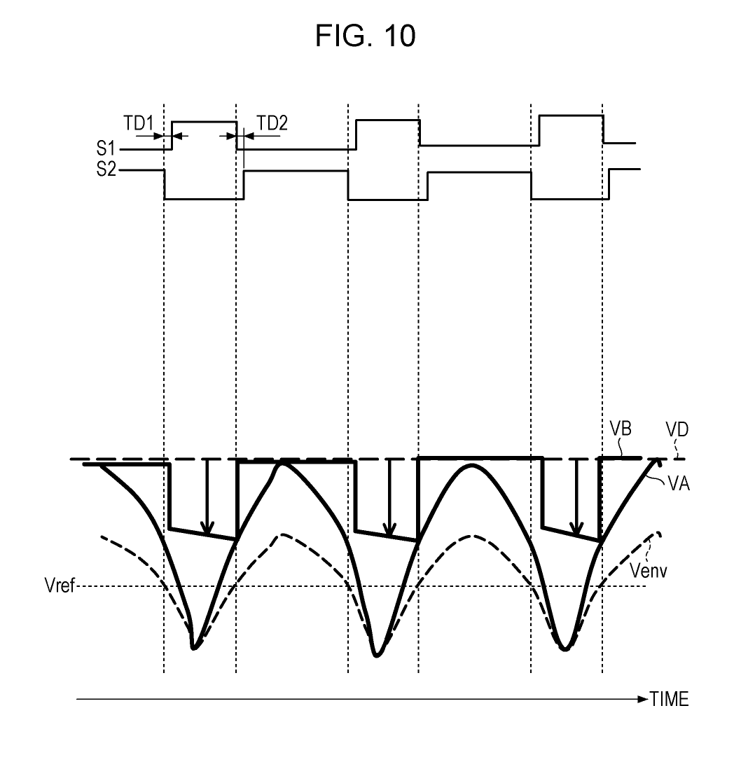

FIG. 6 is a diagram illustrating an example of the configuration of the non-overlap circuit. The non-overlap circuit 52 illustrated in FIG. 6 includes NOR circuits 54 and 55 that perform a NOR operation, an inverter 53 that performs a NOT operation, and delay sections 56 and 57 that delay an input signal and output the signal. The determination signal Vc is input to the NOR circuit 54 and is input to the NOR circuit 55 via the inverter 53. The output signal of the NOR circuit 54 is input to the NOR circuit 55 via the delay section 57. The output signal of the NOR circuit 55 is input to the NOR circuit 54 via the delay section 56. The non-overlap circuit 52 having such a configuration outputs a pair of switch signals S1 and S2 that have dead times TD1 and TD2 respectively (refer to waveforms illustrated in FIGS. 8 and 10).

In FIG. 5A, if the comparator 51 of the monitor circuit 50A detects that the envelope voltage Venv is higher than the reference voltage Vref, the switched-capacitor circuit 60A raises the direct current voltage VD so as to generate the power source voltage VB twice the direct current voltage VD (refer to FIG. 8).

As illustrated in FIG. 5A, the switched-capacitor circuit 60A includes switches 61, 62, and 63, and a capacitor 64. The switch 61 has one end to which the direct current voltage VD is supplied, and the other end that is connected to one end of the capacitor 64 and the supply line 47. The switch 62 has one end to which the direct current voltage VD is supplied, and the other end that is connected to the other end of the capacitor 64 and one end of the switch 63. The switch 63 has one end which is connected to the other end of the switch 62 and the other end of the capacitor 64, and the other end which is connected to ground (GND).

The switches 61 and 63 are turned on or off in accordance with the switch signal S1. When the switch signal S1 is a high level, the switches 61 and 63 are turned on, and when switch signal S1 is a low level, the switches 61 and 63 turn off. The switch 62 is turned on or off in accordance with the switch signal S2. When the switch signal S2 is a high level, the switch 62 is turned on, and when the switch signal S2 is a low level, the switch 62 is turned off. The switches 61, 62, and 63 are individually transistors, for example, a metal oxide semiconductor field effect transistor (MOSFET), or the like.

The switched-capacitor circuit 60A has a configuration as illustrated in FIG. 5A and operates in accordance with the switch signals S1 and S2 so as to supply the power source voltage VB twice the direct current voltage VD to the output stage 43A.

In FIG. 5A, the output stage 43A has a current mirror 70. The current mirror 70 is a high-side circuit disposed at the side of the power source voltage VB with respect to the output node of the power output 41a. The current mirror 70 connected to the supply line 47 of the power source voltage VB operates in accordance with the amplified outputs INN and INP so that the output stage 43 outputs the power output 41a. By the operation of the current mirror 70 connected to the supply line 47 of the power source voltage VB, it is possible to reduce the impact of the variations of the power source voltage VB on the power output 41a. Accordingly, even if the power source voltage VB varies, it is possible to reduce deterioration of the control precision of the power source voltage VA.

The output stage 43A includes a transistor 72, to which the amplified output INP is input, between an input transistor 73 of the current mirror 70 and ground. Also, the output stage 43A includes a transistor 71, to which the amplified output INN is input, between an output transistor 74 of the current mirror 70 and ground. The transistors 71 and 72 individually function as source-grounded amplifiers. The transistors 71 and 72 are examples of the low-side transistors disposed at the ground side with respect to the output node of the power output 41a, and for example, N-channel MOSFETs. The transistor 71 performs amplification operation in accordance with the amplified output INN, and the transistor 72 performs amplification operation in accordance with the amplified output INP. The input transistor 73 and the output transistor 74 are, for example, P-channel MOSFETs.

The output stage 43A includes a pair of source-grounded transistors 71 and 72, and a current mirror 70 which performs mirror conversion on the output current of the drain of the transistor 72 and supplies the output current to the drain of the transistor 72. The power output 41a is output from the output node to which the drain of the output transistor 74 and the drain of the transistor 71 are connected.

FIG. 7 is a diagram illustrating an example of the configuration of the switching regulator. The switching regulator 44 illustrated in FIG. 7 includes a switching amplifier section 45 and an inductor 46. The switching amplifier section 45 operates by the direct current voltage VD as the power source voltage. The inductor 46 has one end which is connected to the output end of the switching amplifier section 45, and the other end which is connected to the power terminal 11 of the power amplifier 10. The switching amplifier section 45 includes, for example, transistors 45a and 45b that are alternately turned on. The high-side transistor 45a and the low-side transistor 45b are alternately turned on so that the current flowing through the inductor 46 is switched, and the power output 44a occurs.

FIG. 8 is a timing chart illustrating an example when the switched-capacitor circuit has a step-up configuration. FIG. 8 illustrates an example of the operation waveform of the power source circuit 30A (refer to FIG. 5A) provided with a switched-capacitor circuit 60A having the step-up configuration. The switched-capacitor circuit 60A supplies the power source voltage VB, which is equal to or higher than the power source voltage VA, to the output stage 43A.

If the comparator 51 detects the envelope voltage Venv that is lower than the reference voltage Vref, the switched-capacitor circuit 60A supplies the direct current voltage VD to the output stage 43A as the power source voltage VB without raising the direct current voltage VD. On the other hand, if the comparator 51 detects that the envelope voltage Venv that is equal to or higher than reference voltage Vref, the switched-capacitor circuit 60A raises the direct current voltage VD so as to supply a voltage having a higher voltage value than that of the direct current voltage VD to the output stage 43A as the power source voltage VB.

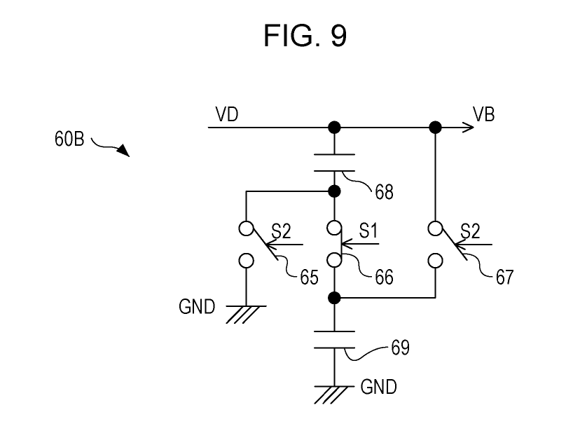

FIG. 9 is a diagram illustrating an example when the switched-capacitor circuit has a step-down configuration. The switched-capacitor circuit 60A having the step-up configuration illustrated in FIG. 5A may be replaced with a switched-capacitor circuit having the step-down configuration (for example, a switched-capacitor circuit 60B illustrated in FIG. 9).

The switched-capacitor circuit 60B lowers the direct current voltage VD so as to generate the power source voltage VB that is lower than the direct current voltage VD. In the case of the configuration in FIG. 9, for example, if each capacitance of the capacitors 68 and 69 is the same, the switched-capacitor circuit 60 generates the power source voltage VB 0.5 times the direct current voltage VD. The step-down rate differs in accordance with each capacitance of the capacitors 68 and 69.

The switched-capacitor circuit 60B includes switches 65, 66, and 67, and capacitors 68 and 69. A circuit in which a capacitor 68, a switch 66, and a capacitor 69 are connected in series is connected between the direct current voltage VD and ground. The switch 65 has one end connected between the capacitor 68 and the switch 66, and the other end connected to ground. The switch 67 has one end to which the direct current voltage VD is supplied, and the other end connected between the switch 66 and the capacitor 69.

The switch 66 is turned on or off in accordance with the switch signal S1. When the switch signal S1 is a high level, switch 66 is turned on, and when the switch signal S1 is a low level, switch 66 is turned off. The switches 65 and 67 are turned on or off in accordance with the switch signal S2. When the switch signal S2 is a high level, the switches 65 and 67 are turned on, and when the switch signal S2 is a low level, the switches 65 and 67 are turned off. The switches 65, 66, and 67 are individually transistors, for example, MOSFETs, or the like.

The switched-capacitor circuit 60B has a configuration, as illustrated in FIG. 9, which operates in accordance with the switch signals S1 and S2 so as to supply the power source voltage VB, which is lower than the direct current voltage VD, to the output stage 43A.

FIG. 10 is a timing chart illustrating an example when the switched-capacitor circuit has a step-down configuration. FIG. 10 illustrates an example of the operation waveform of the power source circuit in which the switched-capacitor circuit 60A in FIG. 5A is replaced with the switched-capacitor circuit 60B in FIG. 9. The switched-capacitor circuit 60B supplies the power source voltage VB, which is equal to or higher than the power source voltage VA, to the output stage 43A.

If the comparator 51 detects the envelope voltage Venv that is higher than the reference voltage Vref, the switched-capacitor circuit 60B does not lower the direct current voltage VD and supplies the direct current voltage VD to the output stage 43A as the power source voltage VB. On the other hand, if the comparator 51 detects the envelope voltage Venv that is lower than or equal to the reference voltage Vref, the switched-capacitor circuit 60B lowers the direct current voltage VD and supplies a voltage having a voltage value lower than that of the direct current voltage VD to the output stage 43A as the power source voltage VB.

In this manner, if the switched-capacitor circuit has a step-down configuration, the average power source voltage of the linear regulator 41A decreases, and thus it is possible to reduce the power consumption. The step-down configuration is particularly effective when the current value demanded for the output of the power amplifier 10 is low, and the output voltage of the power amplifier 10 does not have to be raised.

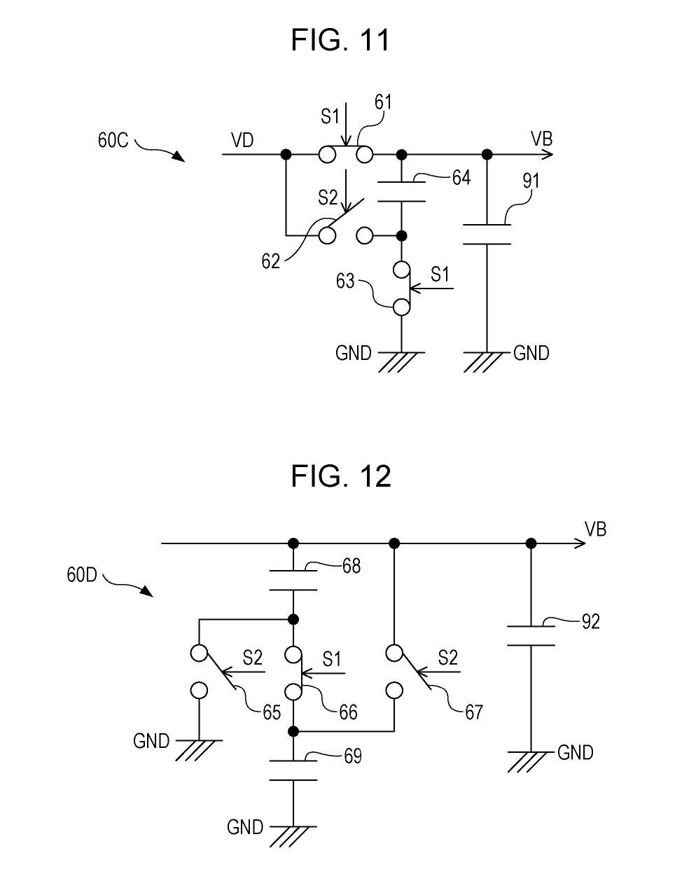

FIG. 11 is a diagram illustrating an example when the switched-capacitor circuit has another step-up configuration. In the switched-capacitor circuit 60C illustrated in FIG. 11, a capacitor 91 is added to the switched-capacitor circuit 60A illustrated in FIG. 5A. The capacitor 91 has one end connected to the supply line 47 of the power source voltage VB, and the other end connected to ground. By adjusting each capacitance of the capacitors 64 and 91, it is possible to adjust the voltage value at the time of raising the power source voltage VB.

FIG. 12 is a diagram illustrating an example when the switched-capacitor circuit has another step-down configuration. In the switched-capacitor circuit 60D illustrated in FIG. 12, a capacitor 92 is added to the switched-capacitor circuit 60B illustrated in FIG. 9. The capacitor 92 has one end connected to the supply line 47 of the power source voltage VB and the other end connected to ground. By adjusting each capacitance of the capacitors 68, 69, and 92, it is possible to adjust the voltage value at the time of lowering the power source voltage VB.

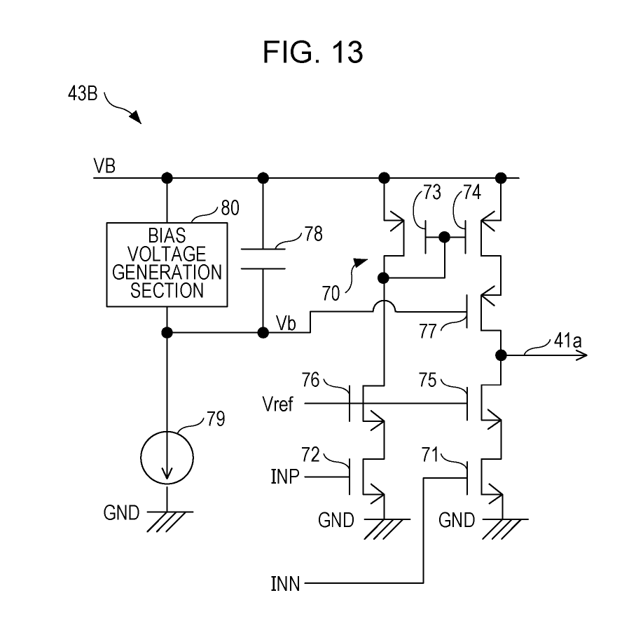

FIG. 13 is a diagram illustrating another example of the configuration of the output stage. The output stage 43B illustrated in FIG. 13 has a cascode configuration in which a plurality of (two in the case illustrated in FIG. 13) transistors 72 and 76 are cascode-connected between the input transistor 73 of the current mirror 70 and ground. Also, the output stage 13B has a cascode configuration in which a plurality of (two in the case illustrated in FIG. 13) transistors 71 and 75 are cascode-connected between the output transistor 74 of the current mirror 70 and ground.

By disposing such a cascode configuration, it is possible to increase the withstand voltage of the output stage 43B with respect to an increase in the power source voltage VB.

For example, the transistors 75 and 76 are N-channel MOSFETs, and the bias between the transistors 75 and 76 is the reference voltage Vref or the direct current voltage VD.

The output stage 43B further includes a transistor 77, a capacitor 78, a bias voltage generator 80, and a fixed current source 79. The transistor 77 is an example of the high-side transistor that is cascode-connected to the output transistor 74. The transistor 77 is, for example, a P-channel MOSFET. The capacitor 78 is connected between the supply line 47 of the power source voltage VB and the gate of the transistor 77. The bias voltage generator 80 is a circuit that generates the bias voltage Vb supplied to the transistor 77 based on the power source voltage VB. The fixed current source 79 is a circuit that supplies a fixed current to the bias voltage generator 80.

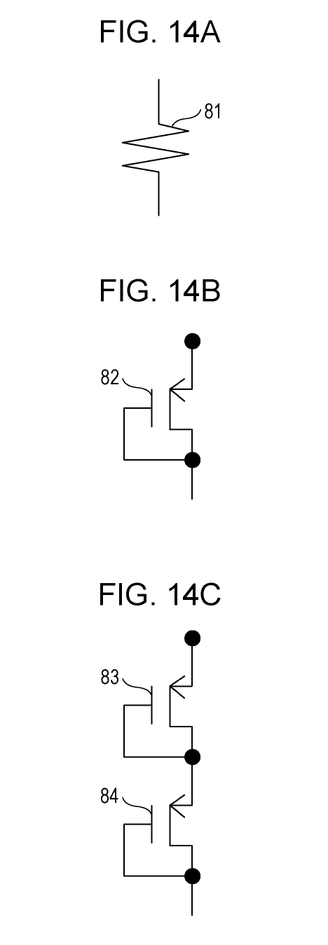

FIGS. 14A, 14B, and 14C are diagrams illustrating a plurality of respective examples of the configuration of the bias voltage generator. The bias voltage generator 80 may be a resistor element 81, a P-channel transistor 82 in which the gate and the drain are connected (diode-connected), or a configuration in which diode-connected P-channel transistors 83 and 84 are connected in series.

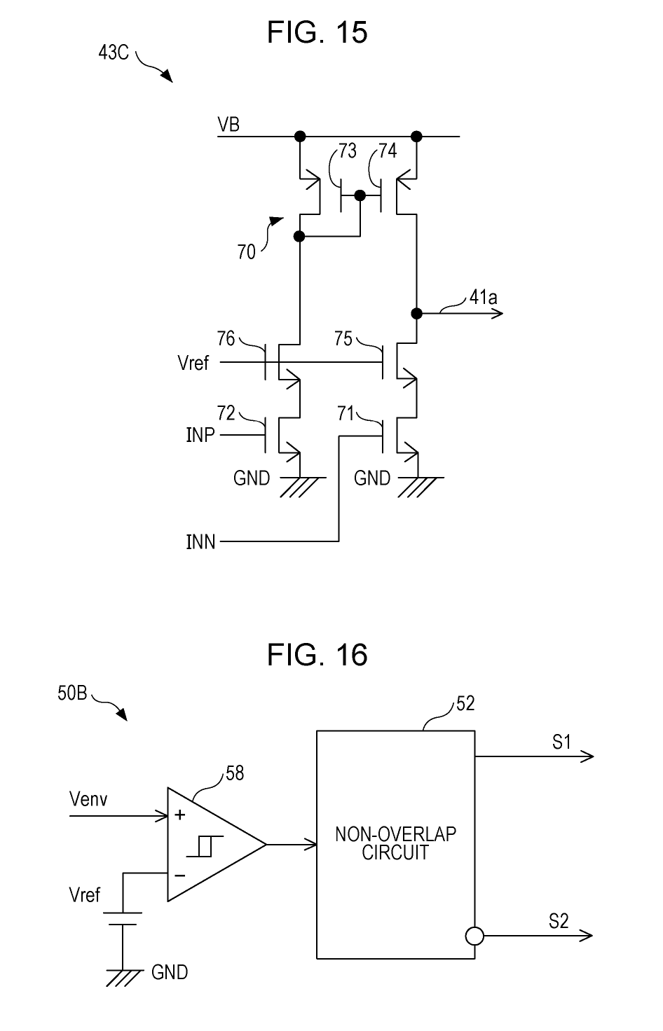

FIG. 15 is a diagram illustrating another example of the configuration of the output stage. The output stage 43C illustrated in FIG. 15 has a configuration in which the bias voltage generator 80, the fixed current source 79, the capacitor 78, and the transistor 77 are removed from the output stage 43B illustrated in FIG. 13. When the power source voltage VB is high, the voltage of the power output 41a is also high, and thus a high voltage is not applied to each drain-source voltage of the P-channel input transistor 73 and the output transistor 74. Accordingly, it is possible to increase the withstand voltage of the output stage 43C without having the bias voltage generator 80, or the like.

FIG. 16 is a diagram illustrating another example of the configuration of the monitor circuit. The monitor circuit 50B includes a comparator 58 having an adjustment function that adjusts the value of the reference voltage Vref. Thereby, even if the power source circuit has variations in characteristic due to individual difference, it is possible to make a fine adjustment of the start timing and the end timing of raising and lowering the direct current voltage VD. Accordingly, it is possible to reduce deterioration of the control precision of the power source voltage VA.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A power source circuit comprising:
a linear regulator including:
an amplifier configured to amplify an envelope signal for representing an envelope of an input signal input into a power amplifier, and
an output stage including transistors, configured to output power output to be supplied to the power amplifier in accordance with amplified output of the amplifier;
a monitor circuit configured to monitor the envelope signal; and
a switched-capacitor circuit configured to generate a power source voltage higher than a voltage of the power output based on a monitoring result of the monitor circuit,
wherein the switched-capacitor circuit does not supply the power source voltage to the amplifier, but supplies the power source voltage to the output stage.

2. The power source circuit according to claim 1,
wherein the output stage includes a current mirror connected to a supply line of the power source voltage, and the current mirror operates in accordance with the amplified output so as to output the power output.

3. The power source circuit according to claim 2,
wherein the output stage includes low-side transistors configured to receive respective inputs of the amplified output between an input transistor of the current mirror and ground, and between an output transistor of the current mirror and the ground.

4. The power source circuit according to claim 3,
wherein the output stage has a cascode configuration including a plurality of cascode-connected transistors including the low-side transistor between the input transistor of the current mirror and the ground, and between the output transistor of the current mirror and the ground respectively.

5. The power source circuit according to claim 4,
wherein the output stage includes a high-side transistor cascode-connected to the output transistor and a bias voltage generator configured to generate a bias voltage supplied to the high-side transistor based on the power source voltage.

6. The power source circuit according to claim 1,
wherein the monitor circuit includes a comparator configured to compare a voltage of the envelope signal with a reference voltage, and
when the comparator detects the envelope signal having a voltage higher than the reference voltage, the switched-capacitor circuit generates the power source voltage higher than the power source voltage in the case where the comparator detects the envelope signal having a voltage lower than the reference voltage.

7. The power source circuit according to claim 6,
wherein when the envelope signal has a voltage higher than the reference voltage, the switched-capacitor circuit generates the power source voltage by stepping up a direct current voltage.

8. The power source circuit according to claim 6,
wherein when the envelope signal has a voltage lower than the reference voltage, the switched-capacitor circuit generates the power source voltage by stepping down a direct current voltage.

9. The power source circuit according to claim 6,
wherein the monitor circuit includes a non-overlap circuit configured to drive the switched-capacitor circuit based on a comparison result of the comparator so as to generate the power source voltage.

10. The power source circuit according to claim 9,
wherein the comparator has an adjustment function of adjusting the reference voltage.

11. The power source circuit according to claim 1, further comprising
a switching regulator configured to generate power output supplied to the power amplifier.

12. A communication device comprising:
a power source circuit includes:
a linear regulator including:
an amplifier configured to amplify an envelope signal for representing an envelope of an input signal input into a power amplifier and
an output stage including transistors, configured to output power output to be supplied to the power amplifier in accordance with amplified output of the amplifier;
a monitor circuit configured to monitor the envelope signal;
a switched-capacitor circuit configured to generate a power source voltage higher than a voltage of the power output based on a monitoring result of the monitor circuit; and
an antenna configured to be supplied with the power from the power amplifier,
wherein the switched-capacitor circuit does not supply the power source voltage to the amplifier, but supplies the power source voltage to the output stage.

13. The communication device according to claim 12,
wherein the output stage includes a current mirror connected to a supply line of the power source voltage, and the current mirror operates in accordance with the amplified output so as to output the power output.

14. The communication device according to claim 13,
wherein the output stage includes low-side transistors configured to receive respective inputs of the amplified output between an input transistor of the current mirror and ground, and between an output transistor of the current mirror and the ground.

15. The communication device according to claim 14,
wherein the output stage has a cascode configuration including a plurality of cascode-connected transistors including the low-side transistor between the input transistor of the current mirror and the ground, and between the output transistor of the current mirror and the ground respectively.

16. The communication device according to claim 15,
wherein the output stage includes a high-side transistor cascode-connected to the output transistor and a bias voltage generator configured to generate a bias voltage supplied to the high-side transistor based on the power source voltage.

17. The communication device according to claim 12,
wherein the monitor circuit includes a comparator configured to compare a voltage of the envelope signal with a reference voltage, and
when the comparator detects the envelope signal having a voltage higher than the reference voltage, the switched-capacitor circuit generates the power source voltage higher than the power source voltage in the case where the comparator detects the envelope signal having a voltage lower than the reference voltage.

18. The communication device according to claim 16,
wherein when the envelope signal has a voltage higher than the reference voltage, the switched-capacitor circuit generates the power source voltage by stepping up a direct current voltage.

19. The communication device according to claim 16,
wherein when the envelope signal has a voltage lower than the reference voltage, the switched-capacitor circuit generates the power source voltage by stepping down a direct current voltage.

20. A method of providing a power source voltage provided to a power amplifier, the method comprising:
amplifying, with an envelope signal amplifier, an envelope signal representing an envelope of an input signal input into the power amplifier;
monitoring, with a monitoring circuit, a voltage of the envelope signal;
providing, with an output stage circuit including transistors, a power output to be supplied to the power amplifier amplifying the input signal;
generating, with a switched-capacitor circuit, a power source voltage higher than a voltage of the power output based on the monitoring; and
supplying the generated power source voltage to the output stage circuit and not the envelope signal amplifier.
